(19) United States
(12) Patent Application Publication
(10) Pub. No.: US 2015/0061156 A1
(43) Pub. Date: Mar. 5, 2015

(54) PAD SOLUTIONS FOR RELIABLE BONDS

(71) Applicant: GLOBALFOUNDRIES Singapore Pte. Ltd., Singapore (SG)

(72) Inventors: Yi JIANG, Singapore (SG); Xiaohua ZHAN, Singapore (SG); Wanbing YI, Singapore (SG); Mahesh BHATKAR, Singapore (SG); Yoke Leng LIM, Singapore (SG); Siow Lee CHWA, Singapore (SG); Juan Boon TAN, Singapore (SG); Soh Yun SIAH, Singapore (SG)

(21) Appl. No.: 14/475,592

(22) Filed: Sep. 3, 2014

Related U.S. Application Data
(60) Provisional application No. 61/873,358, filed on Sep. 3, 2013.

(51) Int. Cl. H01L 23/522; H01L 21/768; H01L 23/532

(52) U.S. Cl. CPC H01L 23/5226; H01L 23/53223; H01L 23/53238; H01L 21/76879
USPC 257/774; 438/637

(57) ABSTRACT

A bonding pad and a method of manufacturing a bonding pad are presented. The method includes providing a substrate prepared with circuits component and an interlevel dielectric (ILD) layer with interconnects. A final passivation level is formed on the substrate surface and includes a pad opening. A wire bond in contact with the pad interconnect is formed in the pad opening. The pad interconnect is suitable for, for example, copper wire bond and can avoid the formation of intermetallic compound during wire bonding. This Abstract is submitted with the understanding that it will not be used to interpret or limit the scope or meaning of the claims.

### CROSS-REFERENCE TO RELATED APPLICATION

This application claims the priority benefit of U.S. Provisional Application Ser. No. 61/873,358, filed on Sep. 3, 2013, which is herein incorporated by reference in its entirety.

### BACKGROUND

In semiconductor device fabrication, back-end-of-line (BEOL) wafer processing generally involves creating various interconnecting metal layers that may be interconnected by vias. Wire bonding pads or pad interconnects are connected to the interconnects and are used to connect an integrated circuit (IC) to other ICs or electronic devices. Wire bonds are attached to the wire bonding pads. The wire bonds may include, for example, gold or copper materials. For example, copper wire bonds may be used more commonly due to its low cost.

The present disclosure relates to providing more reliable pad schemes, which are compatible with the materials of the wire bond and pass the chip package interaction (CPI) qualification requirement, and the methods of manufacturing the same.

### SUMMARY

Embodiments of the present disclosure generally relate to pad interconnects in semiconductor devices. In one embodiment, a method of forming a device is disclosed. The method includes providing a substrate prepared with circuits component and a dielectric layer with interconnects. A pad level is formed over the dielectric layer and forming the pad level comprises forming lower and upper pad levels. A primary passivation layer is formed in the lower pad level and patterned to form a pad via opening. The pad via opening exposes an interconnect in the dielectric layer below. A pad interconnect is formed in the upper pad level. The pad interconnect is disposed over the primary passivation layer around the via pad opening and contacts the exposed interconnect in the dielectric layer below. A final passivation layer is formed on the substrate, where the final passivation layer contacts the primary passivation layer and pad interconnect. A pad opening is formed in the final passivation layer to expose the pad interconnect. A wire bond is received at the pad interconnect.

In another embodiment, a method of forming a device is presented. The method includes providing a substrate prepared with circuits component and a dielectric layer with interconnects. A pad level is formed over the dielectric layer and forming the pad level comprises forming lower and upper pad levels. A pad interconnect is formed in the lower pad level. The pad interconnect is disposed over the dielectric layer and contacts the interconnect in the dielectric layer below. A primary passivation layer is formed in the upper pad level and patterned to form a pad via opening. The pad via opening exposes the pad interconnect in the lower pad level. A protective layer covering the primary passivation layer is formed over the substrate and lines the pad via opening. A final passivation layer is formed on the substrate, where the final passivation layer contacts the protective layer. A pad opening is formed in the final passivation layer to expose the pad via opening lined with the protective layer. A wire bond is received at the pad interconnect and the wire bond breaks through the protective layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

The accompanying drawings, which are incorporated in and form part of the specification in which like numerals designate like parts, illustrate preferred embodiments of the present disclosure and, together with the description, serve to explain the principles of various embodiments of the present disclosure.

FIG. 1 shows a top view of a semiconductor wafer;

FIG. 2 shows a simplified cross-sectional view of a device;

FIGS. 3a-3b show cross-sectional views of an embodiment of a device;

FIGS. 4a-4b show cross-sectional views of another embodiment of a device;

FIGS. 5a-5b show cross-sectional views of yet another embodiment of a device;

FIGS. 6a-6g show cross-sectional views of a process of forming a device;

FIGS. 7a-7f show cross-sectional views of another process of forming a device; and

FIGS. 8a-8d show cross-sectional views of yet another embodiment of forming a device.

### DETAILED DESCRIPTION

Embodiments generally relate to devices, for example, semiconductor devices or integrated circuits (ICs). More particularly, embodiments relate to forming pad interconnects in ICs. The ICs can be any type of IC, such as dynamic or static random access memories, signal processors, microcontrollers or system-on-chip (SoC) devices. Other types of devices may also be useful. The devices or ICs can be incorporated into or used with, for example, consumer electronic products, or other types of products.

The fabrication of devices may involve the formation of features on a substrate that make up circuit components, such as transistors, resistors and capacitors. The devices are interconnected, enabling the IC to perform the desired functions. To form the features and interconnections, layers are repeatedly deposited on the substrate and patterned as desired using lithographic techniques. For example, a wafer is patterned by exposing a photoresist layer with the pattern on a reticle with an exposure source. After exposure, the photoresist layer is developed, where the pattern of the reticle is transferred to the photoresist, and a photoresist etch mask is created. An etch is performed using the etch mask to replicate the pattern on the wafer below, which may include one or more layers, depending on the stage of the process. In the formation of an IC, numerous reticles may be used for different patterning processes. Furthermore, a plurality of ICs may be formed on the wafer in parallel.

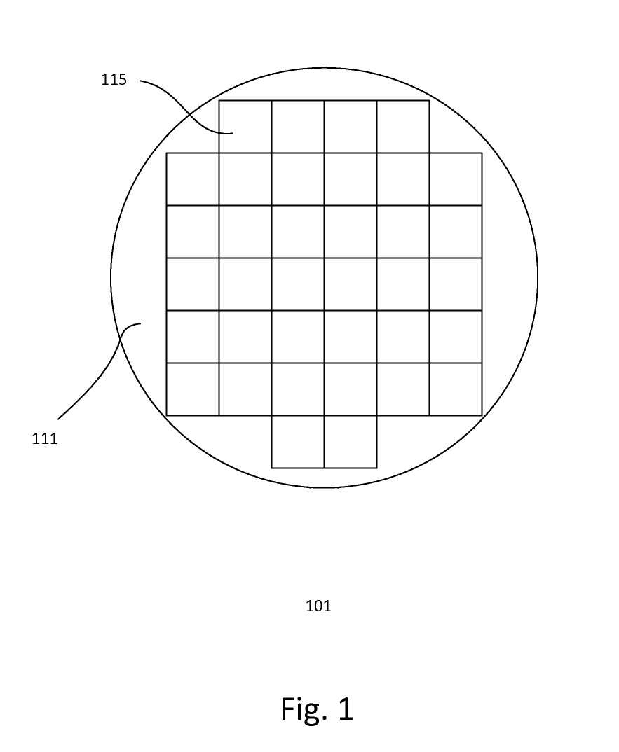

FIG. 1 shows a simplified plan view of an embodiment of a semiconductor wafer 101. The semiconductor wafer, for example, may be a silicon wafer. The wafer may be a lightly doped p-type wafer. Other types of wafers, such as silicon-on-insulator (SOI), or silicon germanium wafer as well as doped with other types of dopants or dopant concentrations may also be useful.

The wafer includes an active surface 111 on which devices 115 are formed. A plurality of devices may be formed on the wafer in parallel. The devices, for example, are arranged in rows along a first (x) direction and columns along a second (y) direction. Separating the devices are dicing channels. After processing is completed, the wafer is diced along the dicing channels to singulate the devices into individual chips.

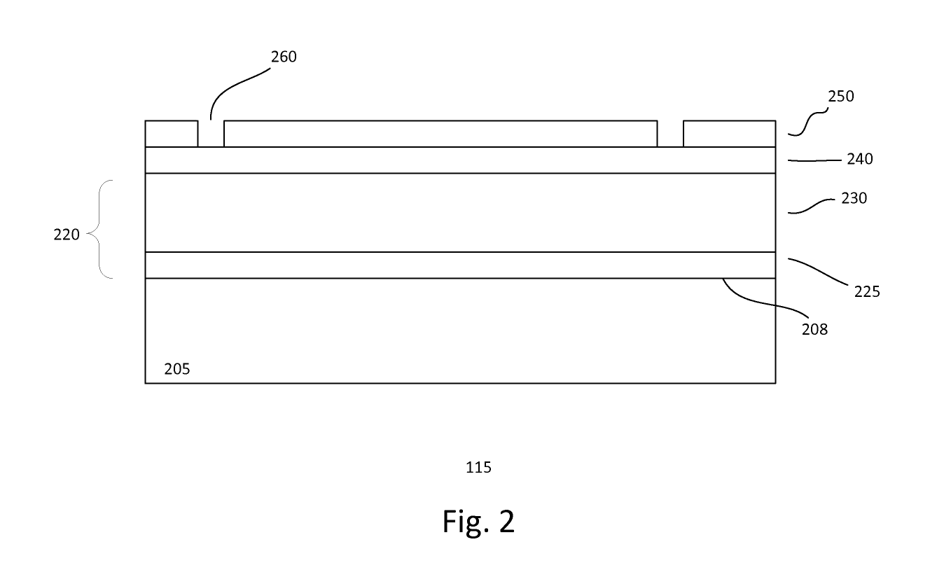

FIG. 2 shows a simplified embodiment of a device 115. The device, for example, is an integrated circuit (IC). Other types of devices may also be useful. The device, for example, may be formed in parallel on a wafer and subsequently singulated. The device includes a substrate 205. The device, for example, may be a part of the wafer, as described in FIG. 1. Common elements may not be described or described in detail. The substrate, for example, may be a semiconductor substrate, such as a silicon substrate. Other types of substrates or wafers may also be useful.

The substrate of the device may include various types of regions. Such regions, for example, may include high voltage (HV), low voltage (LV) and intermediate or medium voltage (MV) regions. High voltage devices or components are formed in the high voltage region, low voltage components are formed in the low voltage region and intermediate voltage components are formed in the intermediate voltage region. The components, for example, are metal oxide semiconductor (MOS) transistors. Other types of components or device regions may also be useful.

Front end of line (FEOL) processing is performed on the substrate. For example, isolation regions are formed to isolate different device regions. The isolation regions, for example, are shallow trench isolation (STI) region. Other types of isolation regions may also be useful. The isolation regions are provided to isolate device regions from other regions. Device wells are formed for p-type and n-type transistors for a complementary MOS (CMOS) device. Separate implants may be employed to form different doped wells using, for example, implant masks, such as photoresist masks. Gates of transistors are formed on the substrate. Gates are formed by, for example, forming gate oxide layer, such as thermal silicon oxide followed by a gate electrode layer, such as polysilicon. The gate electrode may be doped. Other types of gate materials may also be useful. Separate processes may be performed for forming gate dielectrics of the different voltage transistors. This is due to, for example, different gate oxide thicknesses associated with the different voltage transistors. For example, HV transistor will have a thicker gate dielectric than a LV transistor.

The gate layers, in one embodiment, may be formed on the active surface of the substrate 208. After the gate layers are formed on the active surface of the substrate 208, they are patterned to form gates. For example, a photoresist mask may be used for a reactive ion etch (RIE) to pattern the gate layers to form the gates. Source/drain (S/D) regions are formed adjacent to the gates. The S/D regions are heavily doped regions. Depending on the type of device, the S/D regions may be heavily doped n-type or p-type regions. For n-type transistors, S/D regions are heavily doped n-type regions and for p-type transistors, S/D regions are heavily doped p-type regions. Lightly doped regions may be provided for the S/D regions. Dielectric sidewall spacers may be provided on sidewalls of the gates to facilitate forming lightly doped regions. Separate implants may be employed to form different doped regions using, for example, implant masks, such as photoresist mask.

After forming transistors, back-end-of-line (BEOL) processing is performed. The BEOL process includes forming interconnects in interlevel dielectric (ILD) layers 220. The interconnects connect the various components of the IC to perform the desired functions. An ILD layer includes a metal level and a contact level. Generally, the metal level includes conductors or metal lines while the contact level includes contacts. The conductors and contacts may be formed of a metal, such as copper, copper alloy, aluminum, tungsten or a combination thereof. Other suitable types of metal, alloys or conductive materials may also be useful. In some cases, the conductors and contacts may be formed of the same material. For example, in upper metal levels, the conductors and contacts may be formed by dual damascene processes. This results in the conductors and contacts having the same material. In some cases, the conductors and contacts may have different materials. For example, in the case where the contacts and conductors are formed by single damascene processes, the materials of the conductors and contacts may be different. Other techniques, such as reactive ion etch (RIE) may also be employed to form metal lines.

A device may include a plurality of ILD layers or levels. For example, x number of ILD levels may be provided. For example, 5 ILD levels (x=5) may be provided. Other number of ILD levels may also be useful. The number of ILD levels may depend on, for example, design requirements or the logic process involved. A metal level of an ILD level may be referred to as Mᵢ, where i is the i^{th} ILD level of x ILD levels. A contact level of an ILD level may be referred to as Vᵢ₋₁, where i is the i^{th} ILD level of x ILD levels. For the first contact level, it may be referred to as CA.

The BEOL process, for example, commences by forming a dielectric layer over the transistors and other components formed in the FEOL process. The dielectric layer may be silicon oxide. For example, the dielectric layer may be silicon oxide formed by chemical vapor deposition (CVD). The dielectric layer serves as a premetal dielectric layer or first contact layer of the BEOL process. The dielectric layer may be referred to as CA level of the BEOL process. Contacts are formed in the CA level dielectric layer. The contacts may be formed by a single damascene process. Via openings are formed in the dielectric layer using mask and etch techniques. For example, a pattern resist mask with openings corresponding to the vias is formed over the dielectric layer. An anisotropic etch, such as RIE, is performed to form the vias, exposing contact regions below, such as S/D regions and gates. A conductive layer, such as tungsten is deposited on the substrate, filling the openings. The conductive layer may be formed by sputtering. Other techniques may also be useful. A planarization process, such as CMP, is performed to remove excess conductive material, leaving contact plugs in the CA level.

After forming contacts in the CA level, the BEOL process continues to form dielectric layer over the substrate, covering the CA level dielectric layer. The dielectric layer, for example, serves as a first metal level M1 of the first ILD layer. The dielectric layer, for example, is a silicon oxide layer. Other types of dielectric layers may also be useful. The dielectric layer may be formed by CVD. Other techniques for forming the dielectric layer may also be useful.

Conductive lines are formed in the M1 level dielectric layer. The conductive lines may be formed by a damascene technique. For example, the dielectric layer may be etched to form trenches or openings using, for example, mask and etch techniques. A conductive layer is formed on the substrate, filling the openings. For example, a copper or copper alloy layer may be formed to fill the openings. The conductive material may be formed by, for example, plating, such as electro or electroless plating. Other types of conductive layers or forming techniques may also be useful. The first metal level M1 and CA may be referred as a lower ILD level 225.

The process continues to form additional ILD layers. For example, the process continues to form upper ILD levels 230. The upper ILD levels may include ILD level 2 to ILD level x. For example, in the case where x=5 (5 levels), the upper levels include ILD levels from 2 to 5, which includes M2 to M5. The number of ILD layers may depend on, for example, design requirements or the logic process involved. These ILD layers may be referred to as intermediate ILD layers. The intermediate ILD layers may be formed of silicon oxide. Other types of dielectric materials, such as low k, high k or a combination of dielectric materials may also be useful. The ILD layers may be formed by, for example, CVD. Other techniques for forming the ILD layers may also be useful.

The conductors and contacts of the upper ILD layers may be formed by dual damascene techniques. For example, vias and trenches are formed, creating dual damascene structures. The dual damascene structure may be formed by, for example, via first or via last dual damascene techniques. Mask and etch techniques may be employed to form the dual damascene structures. The dual damascene structures are filled with a conductive layer, such as copper or copper alloy. The conductive layer may be formed by, for example, plating techniques. Excess conductive material is removed, forming conductor and contacts in the intermediate ILD layer.

A dielectric liner may be disposed between ILD levels and on the substrate. The dielectric liner, for example, serves as an etch stop layer. The dielectric liner may be formed of a low k dielectric material. For example, the dielectric liner may be nBLOK. Other types of dielectric materials for the dielectric liner may also be useful.

The uppermost ILD level (e.g., x) may have different design rules, such as critical dimension (CD), than the lower ILD levels. For example, the top metal level Mx may have a larger CD than the lower metal levels M1 to Mx-1. For example, the uppermost or top metal level may have a CD which is 2× or 6× the CD of the lower metal levels.

A pad level 240 is disposed over the uppermost ILD level. The pad level includes pad interconnects (not shown). For example, a pad interconnect is coupled to an interconnect in the top metal level Mx. The top metal level Mx is, for example, a copper level. Other types of Mx may also be useful. A final passivation level or layer 250 is disposed over the surface of the pad dielectric layer. The final passivation layer, in one embodiment, includes a polyimide layer. The final passivation layer includes pad openings 260, exposing pad interconnects in the pad level. As shown, two pad openings are provided in the final passivation layer to expose two pad interconnects. However, it is understood that there may be other number of pad openings. The number of pad openings, for example, depends on the number of pad interconnects. The pad interconnects provide external connections to the device.

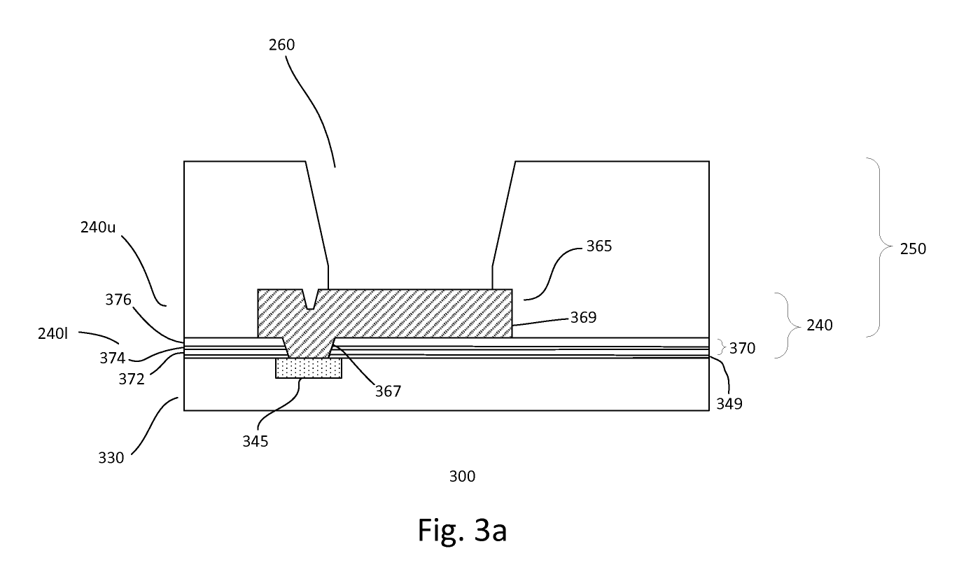

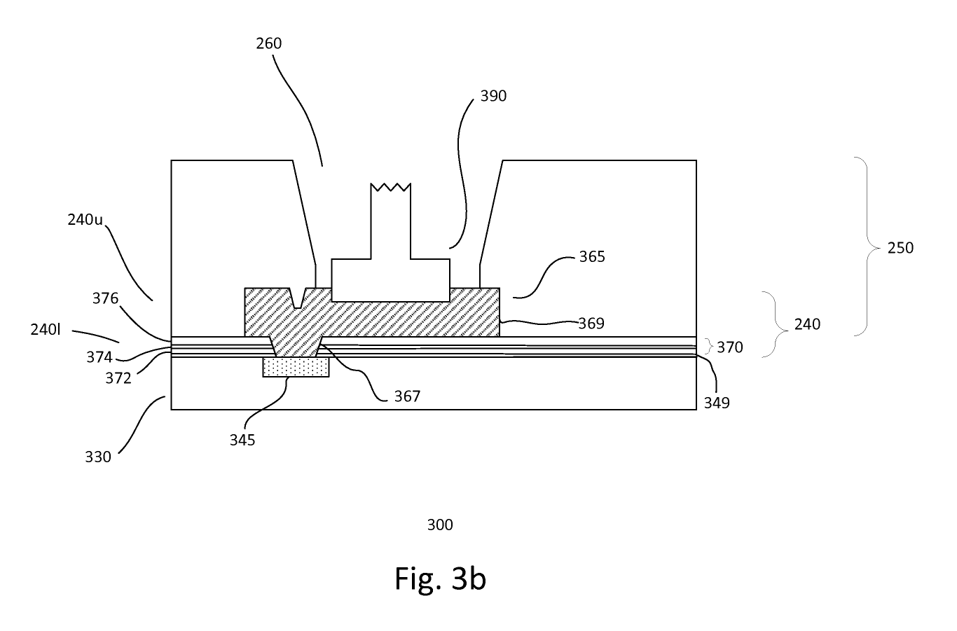

FIGS. 3a-3b show an embodiment of a pad level of a device 300 in greater detail. Although the pad level is shown with one pad interconnect, it is understood the device may include numerous pad interconnects. Referring to FIG. 3a, a simplified portion of a device is shown. An uppermost ILD level 330 of the device is shown. The uppermost ILD level, for example, includes a top metal level Mx with a via level Vx-1. In the case where the device includes 5 metal levels, the uppermost metal level is M5 and the uppermost via level is V4. Other designations or number of metal levels may also be useful. The metal level, as shown, includes an interconnect 345. The interconnect, for example, is a copper interconnect. Other types of interconnects may also be useful.

A dielectric liner 349, in one embodiment, is disposed above the uppermost metal level. The dielectric liner, for example, serves as an etch stop layer. The dielectric liner may be a low k dielectric liner. For example, the dielectric liner may be nBLOK. Other types of dielectric materials for the dielectric liner may also be useful.

A pad level 240 is disposed over the uppermost metal level. In one embodiment, the pad level is disposed over the dielectric liner. For example, the dielectric liner is provided between the uppermost metal level and the pad level. The pad level, for example, includes lower and upper pad levels 240l and 240u.

A primary passivation layer 370 is provided in the pad level. The primary passivation layer, in one embodiment, serves as or is disposed in the lower pad level 240l. In one embodiment, the primary passivation layer is a passivation stack having multiple dielectric passivation layers. In one embodiment, the primary passivation layer includes first, second and third passivation layers 372, 374 and 376. The first and third passivation layers are silicon nitride layers while the second passivation layer is a silicon oxide layer. For example, the nitride layers sandwich the oxide layer.

A pad interconnect 365 is disposed in the pad layer. The interconnect includes a pad via contact 367 and a pad contact 369. The pad via contact is disposed in the primary passivation layer. For example, the primary passivation layer serves as a pad via level. Above the pad via contact is the pad contact. The pad contact is disposed in the upper pad level 240u. The pad via contact electrically couples the pad contact to the interconnect in the uppermost metal level.

The pad interconnect, in one embodiment, is an aluminum pad interconnect. Other conductive materials may also be useful to serve as the pad interconnect. In one embodiment, the via contact and pad contact are an integral unit. For example, the via contact and pad contact are formed from the same conductive layer. For example, the via contact and pad contact are formed from the same aluminum layer. Other configurations of the pad interconnects may also be useful. The thickness of the aluminum pad contact, for example, may be about 2.8 μm. Other thicknesses may also be useful.

In one embodiment, a final passivation layer 250 is disposed over the substrate. The final passivation layer covers the primary passivation layer and pad contact. In one embodiment, the final passivation layer is a polyimide layer. The polyimide layer, for example, provides good adhesion to the pad contact and/or primary passivation layer. In one embodiment, the final passivation layer is a photosensitive polyimide layer. Other types of polyimide may also be useful. The final passivation layer may be, for example, about 5 μm thick. Other thicknesses may also be useful. The final passivation layer, for example, includes a pad opening 260, exposing the pad interconnect in the pad level.

After the wafer is diced to separate the devices into individual chips, assembly may be performed. Assembly, in one embodiment, includes wire bonding. For example, a wire bond 390 is bonded to the pad, as shown in FIG. 3b. The wire bond is, for example, a copper wire bond. Other types of wire bonds, such as but not limited to gold wire bonds, may also be useful.

As described, the device includes one pad interconnect. However, it is understood that a device may include numerous pad interconnects which are bonded with wire bonds. Furthermore, the primary passivation layer avoids the need to form a secondary passivation layer over the pad interconnect and under the final passivation layer, as required in conventional applications. This results in eliminating a mask and etch process necessary to pattern a secondary passivation layer, resulting in cost savings as well as increased throughput.

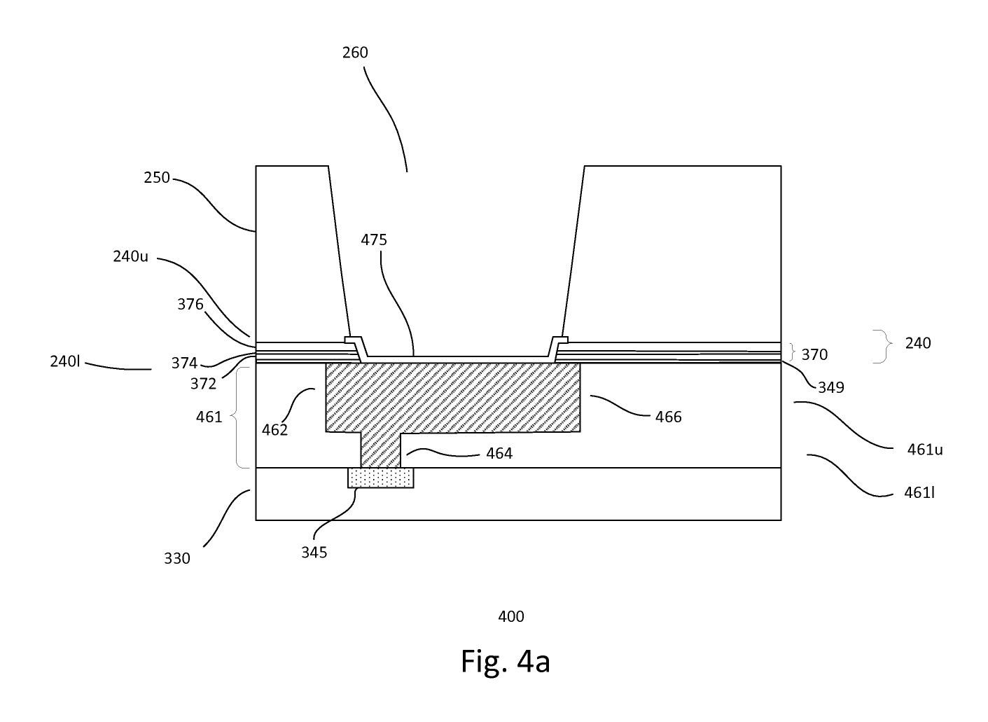

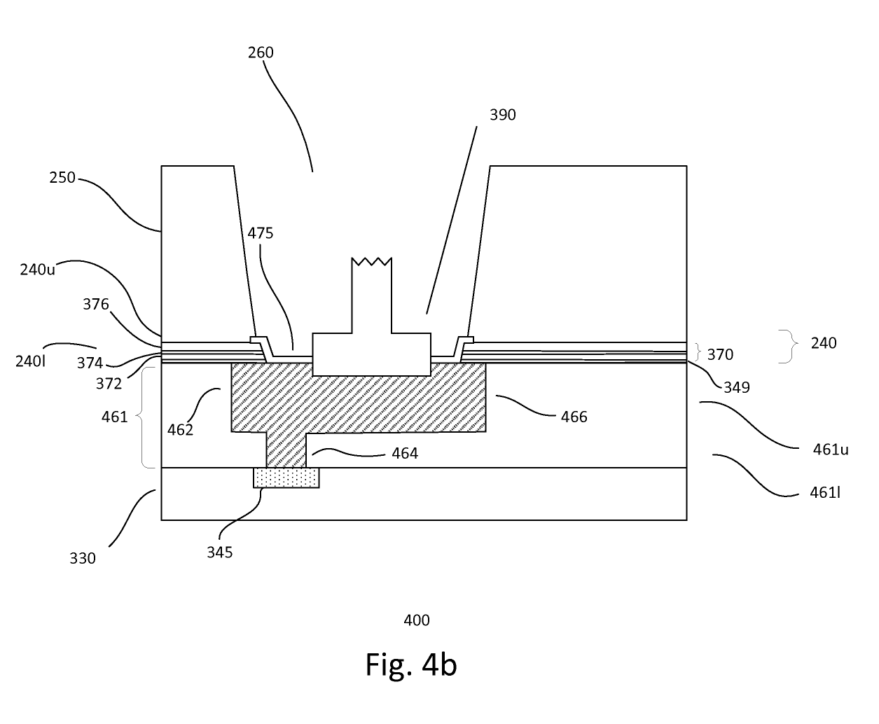

FIGS. 4a-4b show another embodiment of a pad level of a device 400. The device is similar to that described in FIGS. 3a-3b. Common elements may not be described or described in detail. Referring to FIG. 4a, a simplified portion of a device is shown. An uppermost ILD level 330, such as Mx and Vx-1, is shown. The metal level of the uppermost ILD level, as shown, includes an interconnect 345. The interconnect, for example, is a copper interconnect. Other types of interconnects may also be useful.

A first pad level 461 is disposed over the uppermost metal level. The first pad level, for example, is an ultra-thick metal (UTM) pad level. The UTM pad level may be disposed over a dielectric liner (not shown), separating the uppermost metal level and the pad level. The dielectric liner may be a low k dielectric liner. For example, the dielectric liner may be nBLOK. Other types of dielectric materials for the dielectric liner may also be useful.

The first or UTM pad level includes a dielectric layer with lower and upper UTM pad levels 461l and 461u. The lower UTM pad level serves as a UTM via contact level while the upper UTM pad level serves as a UTM pad contact level. The dielectric layer of the pad level may be a silicon oxide layer. Other types of dielectric layers may also be useful. In one embodiment, a UTM pad interconnect 462 is disposed in the pad dielectric layer. The UTM pad interconnect 462 includes a UTM pad via contact 464 and a UTM pad contact 466. The pad via contact is disposed in the lower pad level and the pad contact is disposed in the upper pad level. The pad via contact electrically couples the pad contact to the interconnect in the uppermost metal level.

The UTM pad interconnect, in one embodiment, is a copper pad interconnect. Other conductive materials may also be useful to serve as the pad interconnect. In one embodiment, the pad via contact and pad contact are an integral unit. For example, the pad via contact and pad contact are formed from the same conductive layer. For example, the pad via contact and pad contact are formed from the same copper layer. Other configurations of the pad interconnects may also be useful. In another embodiment, the pad via contact and pad contact are non-integral units. For example, the pad via contact and pad contact are formed from separate layers. The separate layers are, for example, of the same conductive material, such as copper. Other processes to form the pad via contact and pad contact may also be useful. The thickness of the copper pad contact, for example, may be about 3.3 μm. Other thicknesses may also be useful.

A dielectric liner 349, in one embodiment, is disposed above the first pad level 461. The dielectric liner, for example, serves as an etch stop layer. The dielectric liner may be a low k dielectric liner. For example, the dielectric liner may be nBLOK. Other types of dielectric materials for the dielectric liner may also be useful.

In one embodiment, a second pad level 240 is disposed over the dielectric liner, which is disposed over the first pad level. The second pad level serves as a thin pad level. In one embodiment the second pad level includes lower and upper thin pad levels 240l and 240u. The lower pad level includes a primary passivation layer 370. The primary passivation layer is a passivation stack having multiple dielectric passivation layers. In one embodiment, the primary passivation layer includes first, second and third passivation layers 372, 374 and 376. In one embodiment, the first passivation and third passivation layers are silicon nitride layers while the second passivation layer is a silicon oxide layer. For example, the nitride layers sandwich the oxide layer. Other types of passivation stacks may also be useful. For example, the passivation stack may also be an oxide-nitride stack.

The primary passivation layer includes an opening, exposing the underlying UTM pad interconnect. As shown, the opening is smaller than the underlying UTM pad interconnect. The opening should be sufficient to ensure that the opening does not overlap into the UTM pad dielectric layer. For example, the opening takes into account of process variations to ensure that the process window is satisfied. For example, the opening takes into account wire bonding stresses.

A thin contact pad (or layer) 475 is disposed in the upper thin pad level. The thin contact pad lines the exposed UTM pad interconnect as well as a portion of the lower thin pad level surrounding the opening. The thin protective pad, in one embodiment, is an aluminum pad. A thickness of the contact pad may be, for example, about 0.7 μm. Other types of contact pad or pad thicknesses may also be useful.

In one embodiment, a final passivation layer 250 is disposed over the substrate. The final passivation layer covers the primary passivation layer and thin contact pad. The portion of the final passivation layer surrounding the thin contact pad over the primary passivation layer may serve as the upper thin pad level. For example, the primary passivation layer serves as the lower thin pad level. In one embodiment, the final passivation layer is a polyimide layer. For example, the final passivation layer is a photosensitive polyimide layer. The passivation layer may be, for example, about 5 μm thick. Other types of passivation layers or thicknesses may also be useful. The final passivation layer includes a pad opening 260, exposing the thin contact pad.

After the wafer is diced to separate the devices into individual chips, assembly may be performed. Assembly, in one embodiment, includes wire bonding. For example, a wire bond 390 is bonded to the pad, as shown in FIG. 4b. Wire bonding stresses, such as shear strength or hardness, causes the wire bond to penetrate through (or splash) the thin contact pad and into the UTM pad contact below. The wire bond is, for example, a copper wire bond. Other suitable types of wire bonds may also be useful.

As described, a thin contact pad is provided over the UTM pad contact. For example, an aluminum thin contact pad is provided over a copper UTM pad contact. The thin contact pad is much thinner than conventional thick aluminum contact pad. For example, thinner aluminum contact pads allow the bonding force to easily splash the aluminum contact pad to bond the wire bond with the underlying UTM pad contact. Providing a copper UTM pad contact avoids the formation of intermetallic compounds by providing copper-to-copper bonding with the copper wire bond. The copper UTM pad contact may also serve as a stress buffer during wire bonding.

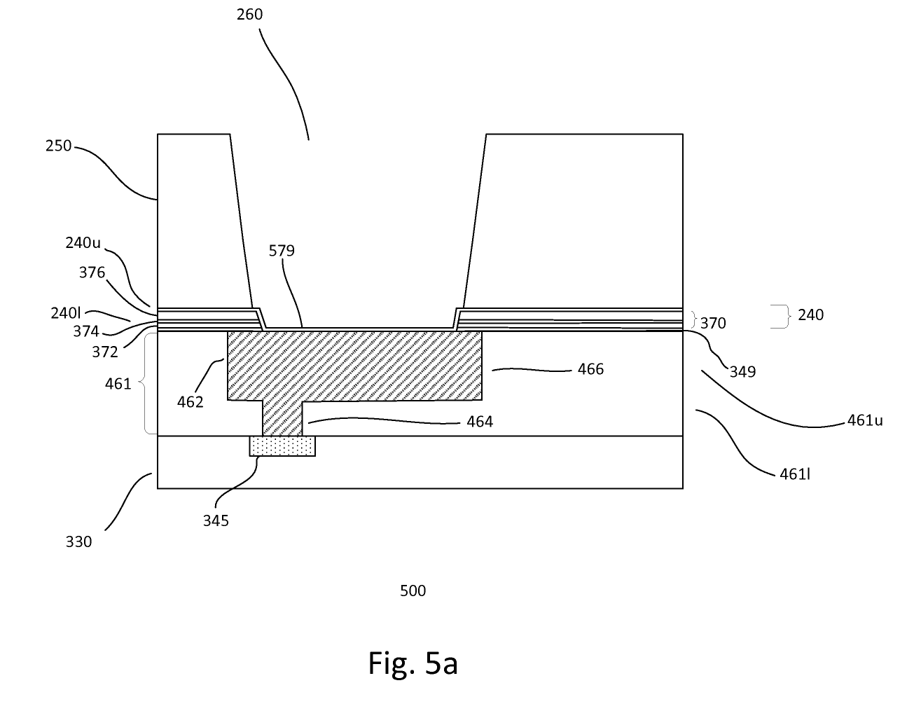

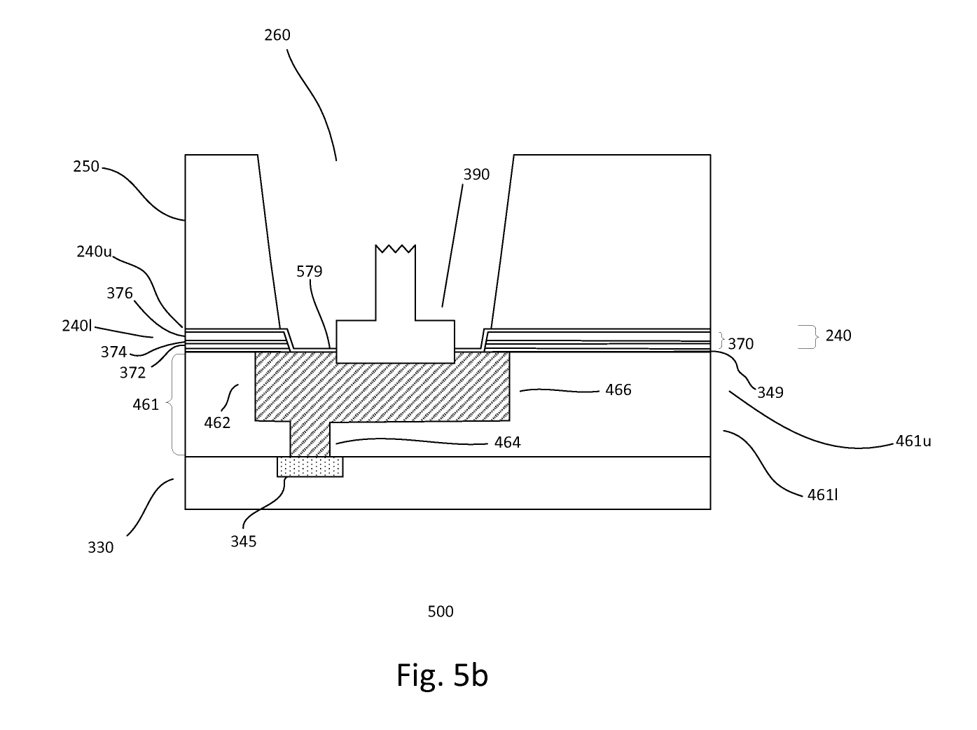

FIGS. 5a-5b show another embodiment of a pad of a device 500 in greater detail. The device is similar to that described in FIGS. 3a-3b and 4a-4b. Common elements may not be described or described in detail. Referring to FIG. 5a, a simplified portion of a device is shown. An uppermost ILD level 330 is shown. The metal level of the uppermost ILD level, as shown, includes an interconnect 345. The interconnect, for example, is a copper interconnect. Other types of interconnects may also be useful.

The UTM pad level includes a dielectric layer with lower and upper UTM pad levels 461l and 461u. The lower UTM pad level serves as a UTM via contact level while the upper UTM pad level serves as a UTM pad contact level. The dielectric layer of the pad level may be a silicon oxide layer. Other types of dielectric layers may also be useful. In one embodiment, a UTM pad interconnect 462 is disposed in the pad dielectric layer. The UTM pad interconnect includes a UTM pad via contact 464 and a UTM pad contact 466. The UTM pad via contact is disposed in the lower UTM pad level and the UTM pad contact is disposed in the upper UTM pad level. The pad via contact electrically couples the pad contact to the interconnect in the uppermost metal level.

The UTM pad interconnect, in one embodiment, is a copper pad interconnect. Other conductive materials may also be useful for the pad interconnect. In one embodiment, the pad via contact and pad contact are an integral unit. For example, the pad via contact and pad contact are formed from the same conductive layer. For example, the pad via contact and pad contact are formed from the same copper layer. Other configurations of the pad interconnects may also be useful. In another embodiment, the pad via contact and pad contact are non-integral units. For example, the pad via contact and pad contact are formed from separate layers. The separate layers are, for example, of the same conductive material, such as copper. Other processes to form the pad via contact and pad contact may also be useful. The thickness of the copper pad contact, for example, may be about 3.3 μm. Other thicknesses may also be useful.

A dielectric liner 349, in one embodiment, is disposed above the first pad level 461. The dielectric liner, for example, serves as an etch stop layer. The dielectric liner may be a low k dielectric liner. For example, the dielectric liner may be nBLOK. Other types of dielectric materials for the dielectric liner may also be useful.

In one embodiment, a second pad level 240 is disposed over the dielectric liner 349, which is disposed over the first pad level. The second pad level serves as a thin pad level. In one embodiment, the second pad level includes a lower and upper thin pad levels 240l and 240u. The lower thin pad level includes a primary passivation layer 370. The primary passivation layer is a passivation stack having multiple dielectric passivation layers. In one embodiment, the primary passivation layer includes first, second and third passivation layers 372, 374 and 376. In one embodiment, the first passivation and third passivation layers are silicon nitride layers while the second passivation layer is a silicon oxide layer. For example, the nitride layers sandwich the oxide layer. Other types of passivation stacks may also be useful. For example, the passivation stack may also be an oxide-nitride stack. The nitride layer is, for example, disposed over the oxide layer for scratch and moisture prevention.

The primary passivation layer includes an opening, exposing the underlying UTM pad interconnect. As shown, the opening is smaller than the underlying UTM pad interconnect. The opening should be sufficient to ensure that the opening does not overlap into the UTM pad dielectric layer. For example, the opening takes into account of process variations to ensure that the process window is satisfied. For example, the opening takes into account wire bonding stresses.

As for the upper thin pad level, it includes a thin protective layer 579. The thin protective layer is disposed over the primary passivation layer and lines the opening over the UTM pad contact, as well as the surface thereof. The thin protective layer, in one embodiment, is a silicon nitride layer. A thickness of the thin protective layer may be, for example, about 7 nm. Other protective layer thicknesses may also be useful.

In one embodiment, a final passivation layer 250 is disposed over the surface of the substrate. The final passivation layer covers the thin protective layer. The thin protective layer may serve as the upper thin pad level. For example, the primary passivation layer serves as the lower thin pad level. In one embodiment, the final passivation layer is a polyimide layer. For example, the final passivation layer is a photosensitive polyimide layer. The passivation layer may be, for example, about 5 μm thick. Other types of passivation layers or thicknesses may also be useful. The final passivation layer includes a pad opening 260, exposing the thin protective layer 579.

After the wafer is diced to separate the devices into individual chips, assembly may be performed. Assembly, in one embodiment, includes wire bonding. For example, a wire bond 390 is bonded to the pad, as shown in FIG. 5b. The bonding force causes the wire bond to penetrate through (or splash) the thin protective layer and into the UTM pad contact below. The wire bond, for example, is a copper wire bond. Other types of wire bonds may also be useful.

As described, a thin protective layer is provided over the UTM pad contact. For example, a thin nitride layer is provided over the copper UTM pad contact. The thin protective layer reduces or prevents oxidation of the copper UTM pad contact. Furthermore, the bonding force easily splashes the thin protective layer to bond the wire bond to the underlying UTM pad contact. In addition, the use of a copper UTM pad contact facilitates copper wire bonding. The copper UTM pad contact may also serve as a stress buffer during wire bonding.

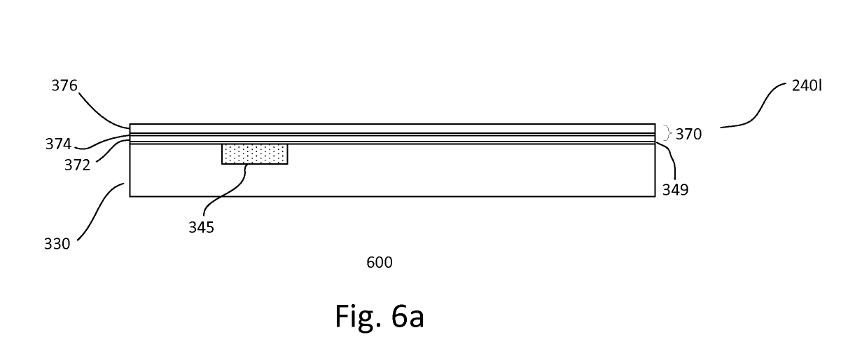

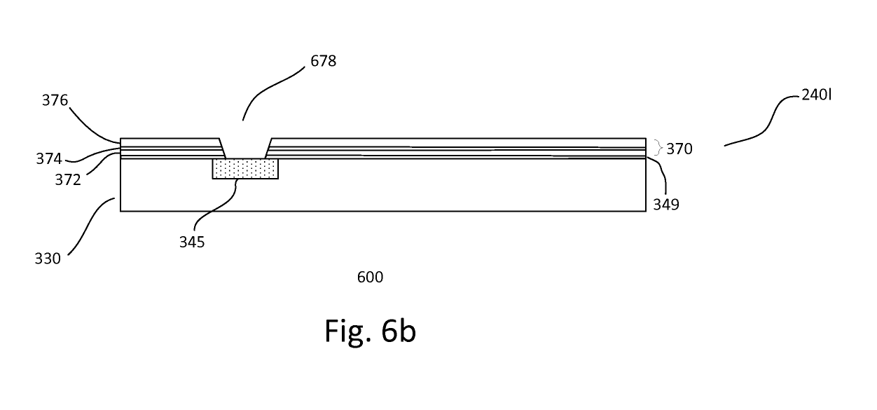

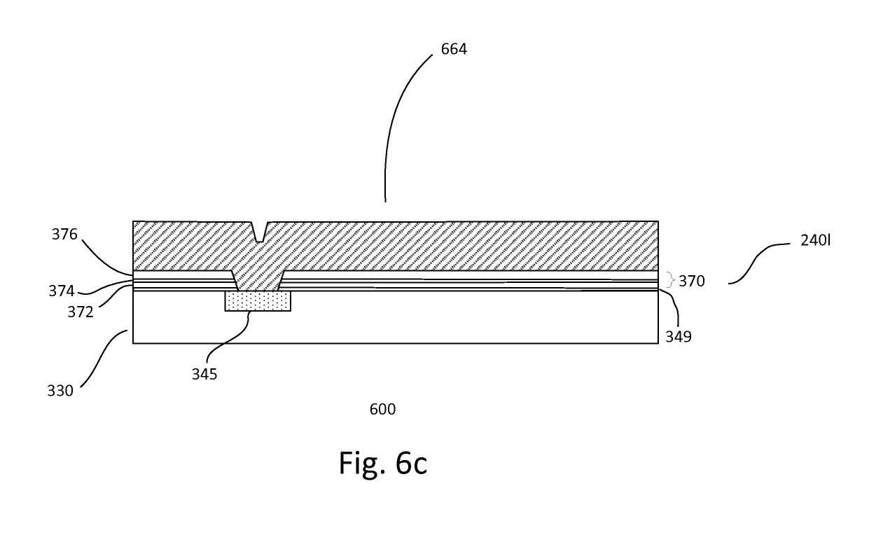

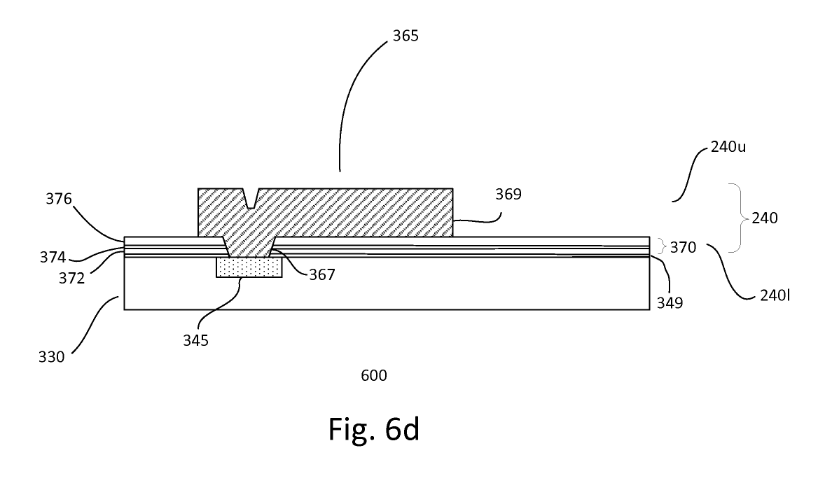

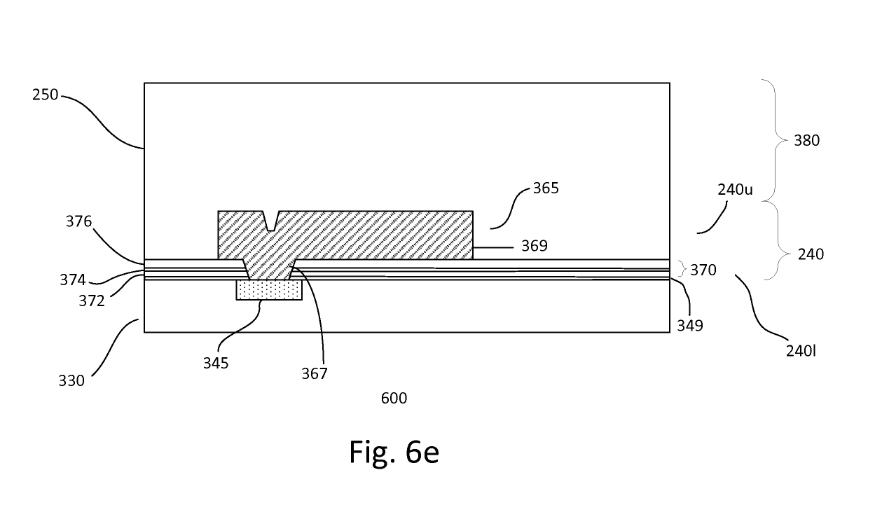

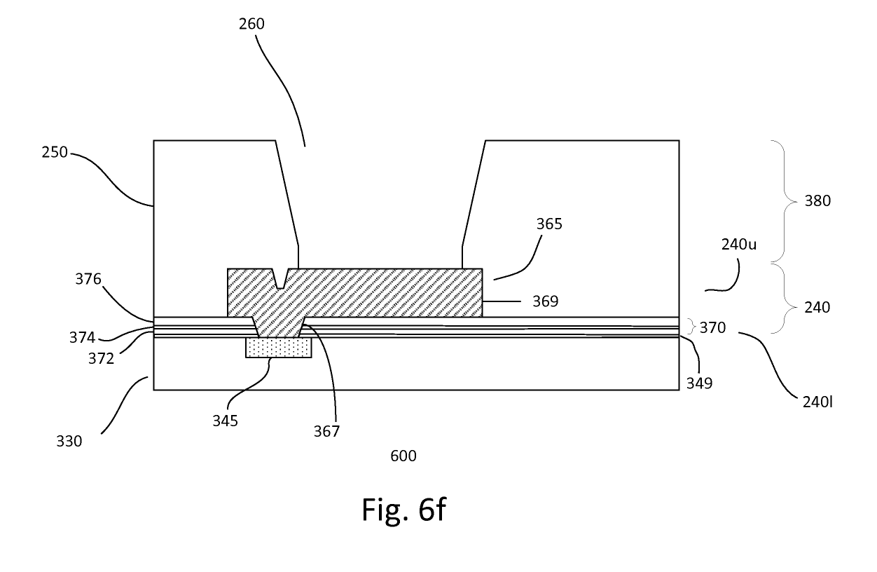

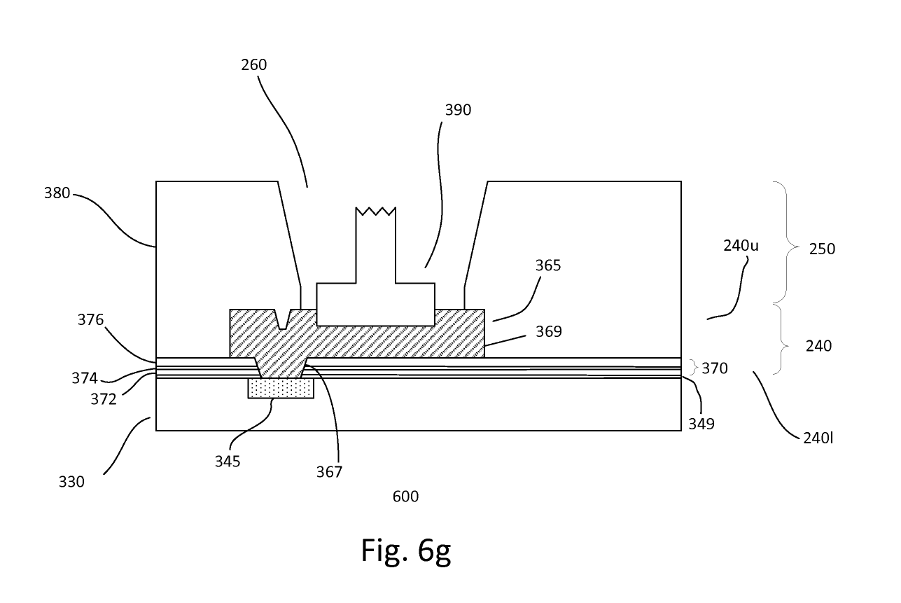

FIGS. 6a-6g show an embodiment of a process for forming a device 600. The process relates to forming pad interconnects in a device. Referring to FIG. 6a, a simplified portion of the device is shown. The device may be similar to that described in FIGS. 2, 3a-3b, 4a-b and 5a-5b. Common elements may not be described or described in detail. The device, for example, includes a substrate (not shown) with ILD levels. An uppermost ILD level 330 is shown. The uppermost ILD level, for example, includes an uppermost or top metal level Mx with via level Vx-1. In the case where the device includes 5 metal levels, the uppermost metal level is M5 and the uppermost via level is V4. Other designations or number of metal levels may also be useful. The metal level, as shown, includes an interconnect 345. The interconnect, for example, is a copper interconnect. Other types of interconnects may also be useful.

A dielectric liner 349, in one embodiment, is disposed above the uppermost metal level. The dielectric liner, for example, serves as an etch stop layer. The dielectric liner may be a low k dielectric liner. For example, the dielectric liner may be nBLOK. Other types of dielectric materials for the dielectric liner may also be useful.

A pad level is disposed over the uppermost metal level. In one embodiment, the pad level is disposed over the dielectric liner. For example, the dielectric liner is provided between the uppermost metal level and the pad level. As shown, a lower pad level 240l is formed over the liner layer. The lower pad level includes a passivation layer 370. In one embodiment, the passivation layer is a primary passivation layer. The primary passivation layer includes first, second and third passivation layers 372, 374 and 376. In one embodiment, the first passivation and third passivation layers are silicon nitride layers while the second passivation layer is a silicon oxide layer. For example, the nitride layers sandwich the oxide layer. The various layers of the primary passivation stack may be formed by, for example, chemical vapor deposition (CVD). Other techniques for forming the layers of the stack may also be useful.

In FIG. 6b, a pad via opening 678 is formed in the primary passivation layer. The opening, for example, is a via opening which exposes the interconnect in Mx. The opening may be formed by mask and etch techniques. For example, a patterned photoresist mask may be formed over the primary passivation layer, serving as an etch mask. An etch, such as RIE, may be performed to pattern the primary passivation layer using the patterned resist etch mask. In one embodiment, the etch transfers the pattern of the mask to the primary passivation layer, including the dielectric liner. This, for example, exposes the interconnect in Mx.

A conductive layer 664 is formed on the substrate, covering the primary passivation layer and filling the pad via opening, as shown in FIG. 6c. The conductive layer serves as a thick pad interconnect layer. In one embodiment, the conductive layer serves as a pad interconnect. In one embodiment, the conductive layer is an aluminum layer. For example, the aluminum layer is used to form an aluminum pad interconnect. Other types of conductive layers may also be useful. In one embodiment, the conductive layer is different from that used to form the interconnect in the uppermost ILD level. For example, the interconnect is copper while the pad interconnect layer is aluminum. Other configurations of the uppermost interconnect and pad interconnect layer may also be useful. The conductive layer may be formed by, for example, sputtering. Other techniques for forming the conductive layer may also be useful. The conductive layer should be sufficiently thick to enable formation of a subsequently formed thick pad contact of a pad interconnect over the primary passivation layer. The conductive layer, for example, may be about 2.8 μm thick over the primary passivation layer. Providing a conductive layer which can accommodate a pad contact of other thicknesses may also be useful.

Referring to FIG. 6d, the conductive layer is patterned to form a pad interconnect 365. Patterning the conductive layer to form the pad interconnect may be achieved by mask and etch techniques. For example, a patterned photoresist mask may be formed over the conductive layer. An etch, such as RIE, may be used to pattern the conductive layer with a patterned resist mask. In one embodiment, the pad interconnect includes a pad via contact 367 in the via opening and a pad contact 369 over the primary passivation layer. The pad contact, for example, is disposed in an upper pad level 240u of the pad level 240.

A final passivation layer 250, as shown in FIG. 6e, is formed on the surface of the substrate. The final passivation layer covers the pad interconnect and primary passivation layer. Forming the final passivation layer may be achieved by a single mask lithography process, such as a spin coating process. For example, the lithography process may be self-planarizing. In one embodiment, the final passivation layer is a polyimide layer, such as a photosensitive polyimide layer. The final passivation layer may be, for example, about 5 μm thick. Other thicknesses may also be useful. In one embodiment, a lower portion of the final passivation layer serves as the upper pad level 240u while an upper portion serves as the final passivation level 380. For example, the portion below the surface of the pad interconnect serves as the upper pad level while the portion above the surface of the pad interconnect serves as the final passivation level. The top surface of the pad interconnect, for example, serves as the interface between the pad level and final passivation level.

In FIG. 6f, a pad opening 260 is formed in the final passivation layer, exposing the pad interconnect in the pad level. To form the pad opening, the final passivation layer may be exposed by an exposure source using a reticle with the desired pattern. After exposure, the polyimide layer is developed to create the opening, transferring the pattern of the reticle to the polyimide layer.

In one embodiment, after forming pad opening, the wafer is diced to separate the devices into individual chips. Referring to FIG. 6g, a wire bonding process bonds the wire bond 390 to the pad contact of the pad interconnect. The wire bond is, for example, a copper wire bond. Other types of wire bonds, such as but not limited to a gold wire bond, may also be useful.

As described, the device includes one pad interconnect. However, it is understood that a device may include numerous pad interconnects which are bonded with wire bonds. Furthermore, the primary passivation layer avoids the need to form a secondary passivation layer over the pad interconnect and under the final passivation layer, as required in conventional applications. This results in eliminating a mask and etch process necessary to pattern a secondary passivation layer, resulting in cost savings as well as increased throughput.

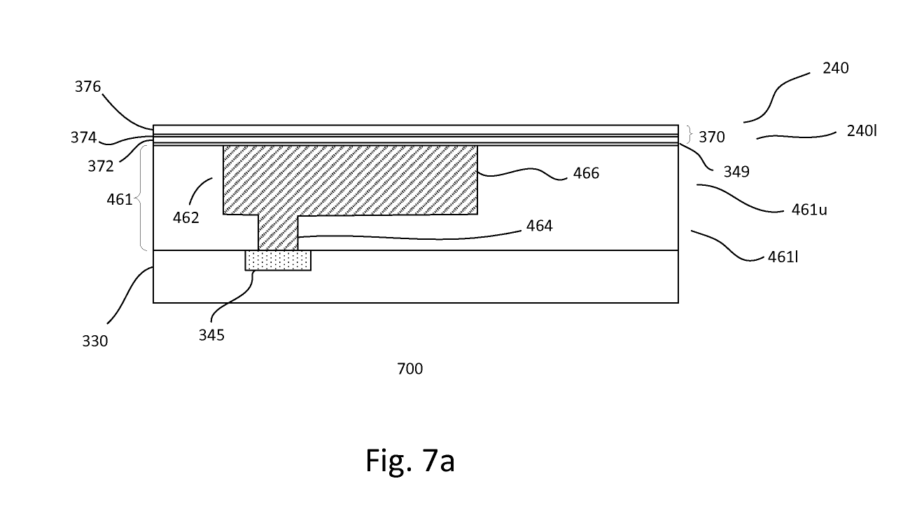

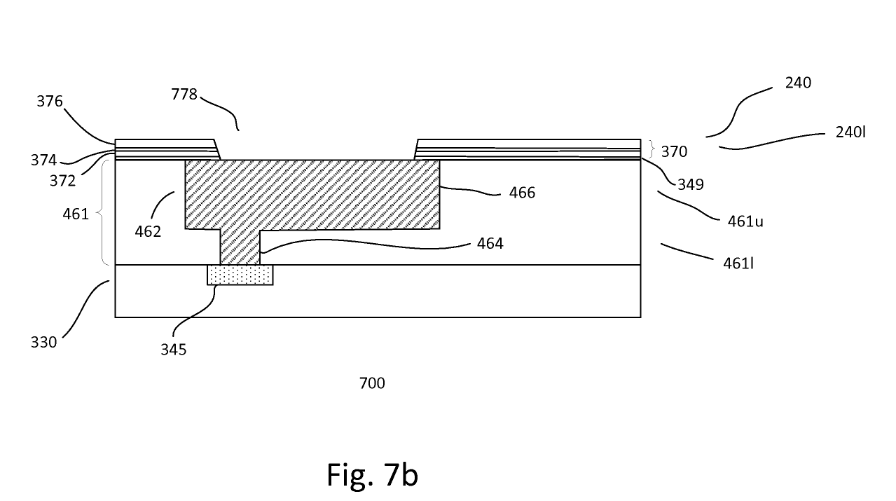

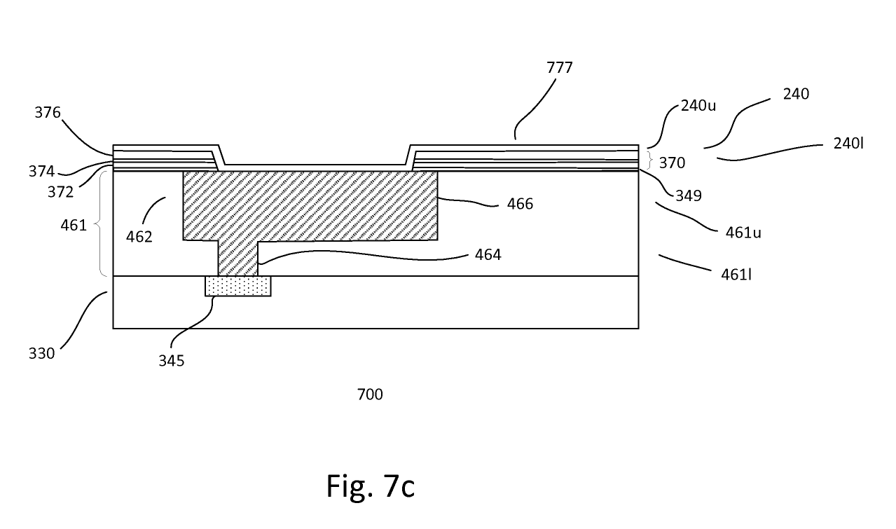

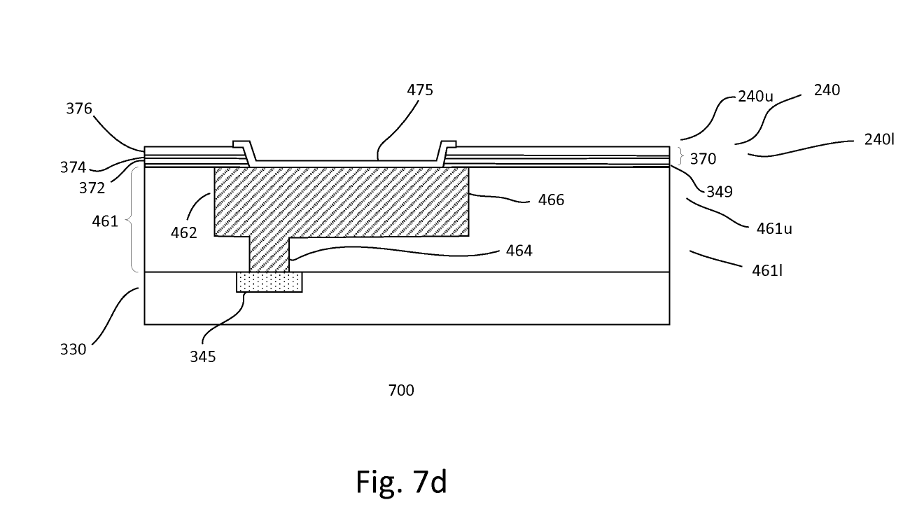

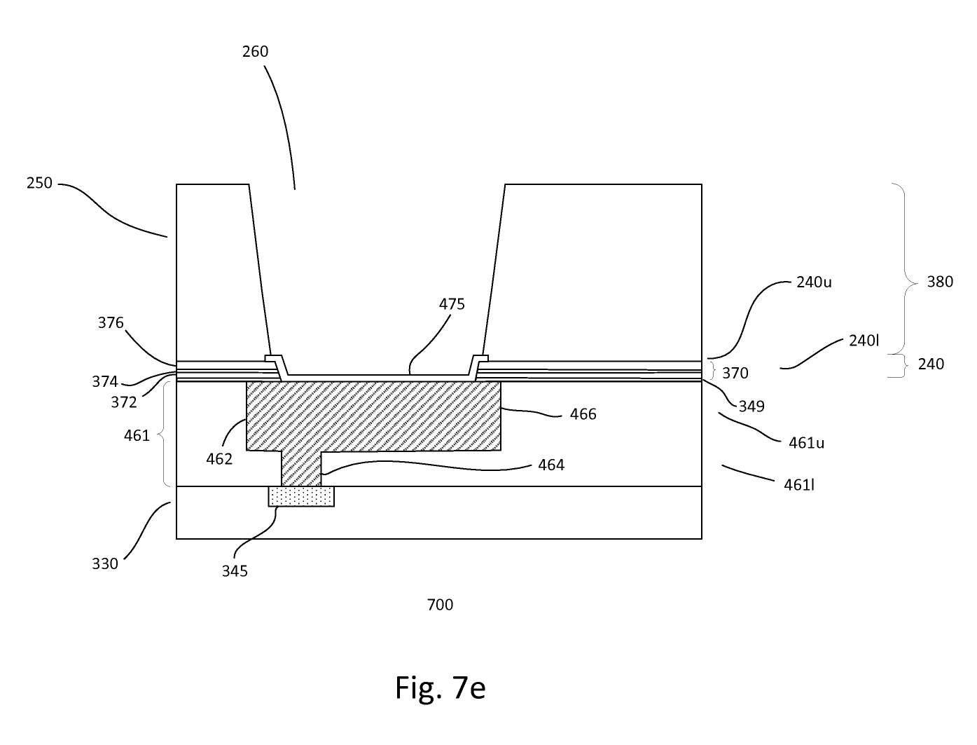

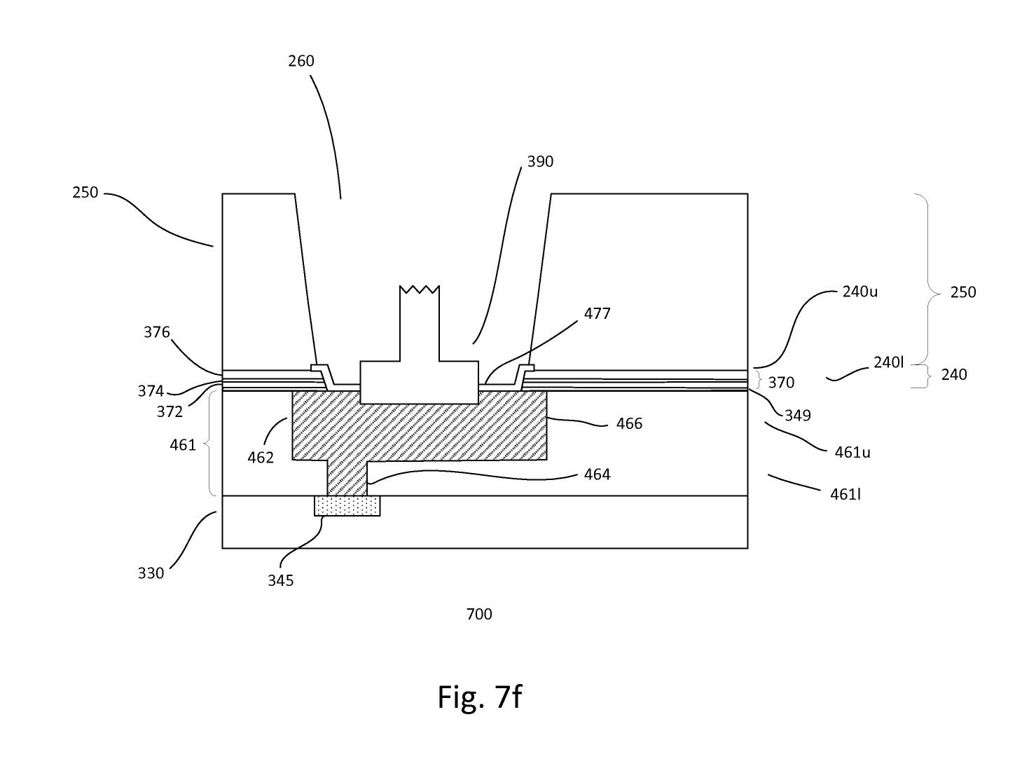

FIGS. 7a-7f show an embodiment of a process for forming a device 700. The process relates to forming pad interconnects in a device. Referring to FIG. 7a, a simplified portion of the device is shown. The device may be similar to that described in FIGS. 2, 3a-3b, 4a-4b, 5a-5b and 6a-6g. Common elements may not be described or described in detail. The device, for example, includes a substrate (not shown) with ILD levels. An uppermost ILD level 330 is shown. The uppermost ILD level, for example, includes metal level Mx with via level Vx-1. In the case where the device includes 5 metal levels, the uppermost metal level is M5 and the uppermost via level is V4. Other designations or number of metal levels may also be useful. The metal level, as shown, includes an interconnect 345. The interconnect, for example, is a copper interconnect. Other types of interconnects may also be useful.

A dielectric liner (not shown) may be formed over the uppermost metal level. The dielectric liner, for example, serves as an etch stop layer. The dielectric liner may be a low k dielectric liner. For example, the dielectric liner may be nBLOK. Other types of dielectric materials for the dielectric liner may also be useful. The dielectric liner may be formed by, for example, CVD. Other techniques for forming the dielectric liner may also be useful.

A first pad level 461 is disposed over the uppermost metal level. The first pad level, for example, is an ultra-thick metal (UTM) pad level. In one embodiment, the UTM pad level includes lower and upper UTM pad levels 461l and 461u. The UTM pad level includes a UTM dielectric layer. In one embodiment, the pad level includes a silicon oxide layer. Other types of pad dielectric layers may also be useful for the UTM pad level. The UTM pad level may be formed by, for example, CVD. Other forming techniques or combination of forming techniques may also be useful.

In one embodiment, a UTM pad interconnect 462 is formed in the pad dielectric layer. The UTM pad interconnect includes a UTM pad via contact 464 and a UTM pad contact 466. The UTM pad via contact is disposed in the lower UTM pad level and the UTM pad contact is disposed in the upper UTM pad level. The pad via contact electrically couples the pad contact to the interconnect in the uppermost metal level. The UTM pad interconnect, in one embodiment, is a copper pad interconnect. Other conductive materials may also be useful to serve as the pad interconnect.

The UTM pad interconnect may be formed by, for example, a single damascene or dual damascene technique. For example, a dual damascene structure is formed in the UTM pad level. The dual damascene structure includes a pad via opening formed in the lower UTM pad level and a pad contact opening is formed in the upper UTM pad level. The UTM pad is, for example, an island in communication with the interconnect in Mx. The dual damascene structure may be formed by mask and etch techniques. The dual damascene structure may be formed by a via first or via last dual damascene technique. Other techniques for forming the dual damascene structure may also be useful.

The dual damascene structure is filled with a conductive layer of the pad interconnect. Excess conductive material is removed by a planarizing process. For example, a CMP is performed to remove excess conductive material. The planarizing process forms a planar surface with the conductive layer and pad dielectric layer. This produces a pad interconnect in the dual damascene structure. Forming the pad interconnect by a dual damascene technique results in a pad interconnect in which the pad via contact and pad contact are an integral structure. Other techniques for forming the pad interconnect may also be useful.

In one embodiment, the conductive layer filling the dual damascene structure is a copper conductive layer. For example, the copper conductive is used to form a copper pad interconnect in the dual damascene structure. The conductive layer, for example, is the same material as that used to form the interconnect in the uppermost metal level, such as Mx. Other configurations of the UTM interconnect and interconnect in the uppermost metal level may also be useful. The conductive layer may be formed by plating techniques. Other techniques for forming the conductive layer may also be useful.

In another embodiment, the pad interconnect may also be a non-integral structure formed by single damascene technique. For example, the pad via contact and pad contact are single damascene structures. The single damascene structures are, for example, separate layers formed by separate mask and etch processes. For example, a first process forms a pad via opening in a lower pad dielectric layer. The pad via opening is filled with a first conductive layer to form a pad via contact in the lower UTM pad level. Excess first conductive material is removed by a planarization process such as CMP. A second process deposits an upper pad dielectric layer over the lower pad dielectric layer and forms a pad contact opening in the upper pad dielectric layer. The pad contact opening is filled with a second conductive layer to form a pad contact in the upper UTM pad level. Excess second conductive material is removed by a planarization process such as CMP. The single damascene structures are, for example, of the same conductive material such as copper.

A dielectric liner 349, for example, may be formed over the UTM pad level with the pad interconnect. The dielectric liner, for example, serves as an etch stop layer. The dielectric liner may be a low k dielectric liner. For example, the dielectric liner may be nBLOK. Other types of dielectric materials for the dielectric liner may also be useful. The dielectric liner may be formed by, for example, CVD. Other techniques for forming the dielectric liner may also be useful.

The process continues to form a second pad level 240. The second pad level, in one embodiment, is a thin pad level. As shown, a lower thin pad level 240l is formed over the substrate. The lower thin pad level, for example, is formed over the dielectric liner. In one embodiment, the lower pad level includes a passivation layer 370. The passivation layer, for example, is a primary passivation layer, similar to that already described. Other types of passivation layers may also be useful. The primary passivation layer includes first, second and third passivation layers 372, 374 and 376. In one embodiment, the first passivation and third passivation layers are silicon nitride layers while the second passivation layer is a silicon oxide layer. For example, the nitride layers sandwich the oxide layer. The various layers of the primary passivation stack may be formed by, for example, chemical vapor deposition (CVD). Other techniques for forming the layers of the stack may also be useful. Other types of passivation stacks may also be useful. For example, the passivation stack may also be an oxide-nitride stack. The nitride layer is, for example, formed over the oxide layer for scratch and moisture prevention.

In FIG. 7b, a pad via opening 778 is formed in the primary passivation layer. The opening, for example, is a thin pad via opening, exposing the pad interconnect in the upper UTM pad level. The opening may be formed by mask and etch techniques. For example, a patterned photoresist mask may be formed over the primary passivation layer, serving as an etch mask. An etch, such as RIE, may be used to pattern the primary passivation layer with a patterned resist etch mask. In one embodiment, the etch removes the primary passivation layer, including the dielectric liner, to expose the pad interconnect.

A protective layer 777 is formed on the substrate, covering the passivation layer and lining the thin pad via opening, as shown in FIG. 7c. The protective layer is a protection layer. In one embodiment, the protective layer is a conductive layer. In one embodiment, the protective layer is an aluminum layer. Other types of protective layers may also be useful. In the case where the protective layer is a conductive layer, it is different from the underlying UTM pad interconnect. Other configurations of protective layer and UTM pad interconnect may also be useful. The conductive protective layer may be formed by, for example, sputtering. Other techniques for forming the protective layer may also be useful. In one embodiment, the protective layer is a thin protective layer. For example, the thickness of the protective layer should be sufficiently thick such that it is suitable to serve as a thin contact pad over the primary passivation layer. The thickness of the protective layer may have a thickness of about, for example, 0.7 μm. Other thicknesses for the protective layer may also be useful.

Referring to FIG. 7d, the conductive protective layer is patterned to form a thin pad interconnect or pad contact 475. Patterning the conductive layer to form the thin contact pad may be achieved by mask and etch techniques. For example, a patterned photoresist mask may be formed over the conductive layer. An etch, such as RIE, may be used to pattern the conductive layer with a patterned resist mask. The thin contact pad lines the exposed UTM pad interconnect as well as a portion of the lower thin pad level surrounding the opening.

A final passivation layer 250, as shown in FIG. 7e, is formed on the surface of the substrate. The final passivation layer covers the pad interconnect and primary passivation layer. Forming the final passivation layer may be achieved by a single mask lithography process, such as a spin coating process. For example, the lithography process is self-planarizing. In one embodiment, the final passivation layer is a polyimide layer, such as a photosensitive polyimide layer. The final passivation layer may be, for example, about 5 μm thick. Other thicknesses may also be useful.

In one embodiment, a lower portion of the final passivation layer serves as an upper pad level 240u while an upper portion serves as the final passivation level 250. For example, the portion below the surface of the thin contact pad serves as an upper thin pad level while the portion above the surface of the thin contact pad serves as the final passivation level. The top surface of the thin contact pad serves as the interface between the pad level and final passivation level.

A pad opening 260 is formed in the final passivation layer, exposing the thin pad contact in the pad level. To form the pad opening, the final passivation layer may be exposed by an exposure source using a reticle with the desired pattern. After exposure, the polyimide layer is developed to create the opening, transferring the pattern of the reticle to the polyimide layer. In one embodiment, the pad opening is smaller than the underlying UTM pad interconnect. For example, the opening does not overlap the UTM pad dieletric layer.

In one embodiment, after forming the pad opening, the wafer is diced to separate the devices into individual chips. Referring to FIG. 7f, a wire bonding process bonds a wire bond 390 to the pad contact of the UTM pad interconnect. The wire bond is, for example, a copper wire bond. Other types of wire bonds may also be useful.

As described, the device includes one pad interconnect. However, it is understood that a device may include numerous pad interconnects which are bonded with wire bonds. Furthermore, a thin contact pad is provided over the UTM pad interconnect. For example, an aluminum thin contact pad is provided over a copper UTM pad interconnect. The thin contact pad is much thinner than conventional thick aluminum contact pads. The use of thinner aluminum contact pads, for example, allow the bonding force to easily splash the aluminum pads to bond the wire bond to the underlying UTM pad contact. Providing a copper UTM pad contact avoids the formation of intermetallic compounds by providing copper-to-copper bonding with the copper wire bond. The copper UTM pad contact may also serve as a stress buffer during wire bonding.

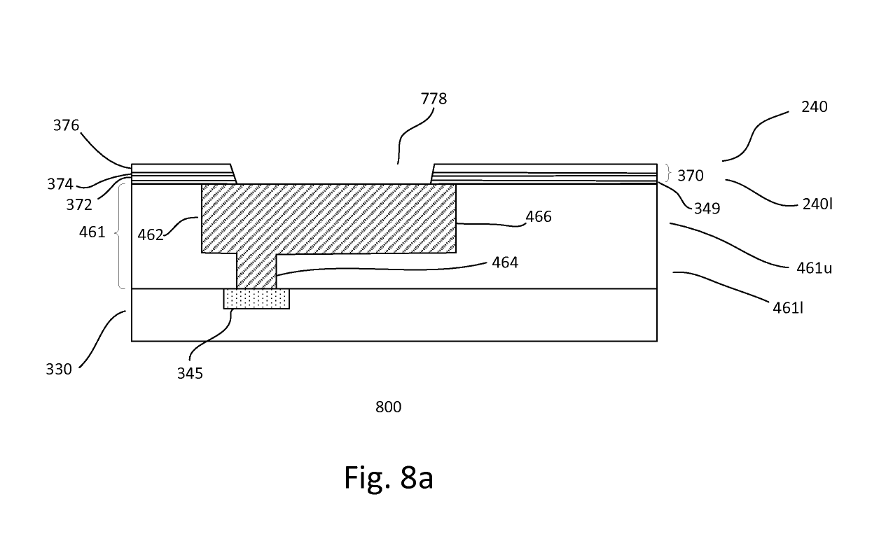

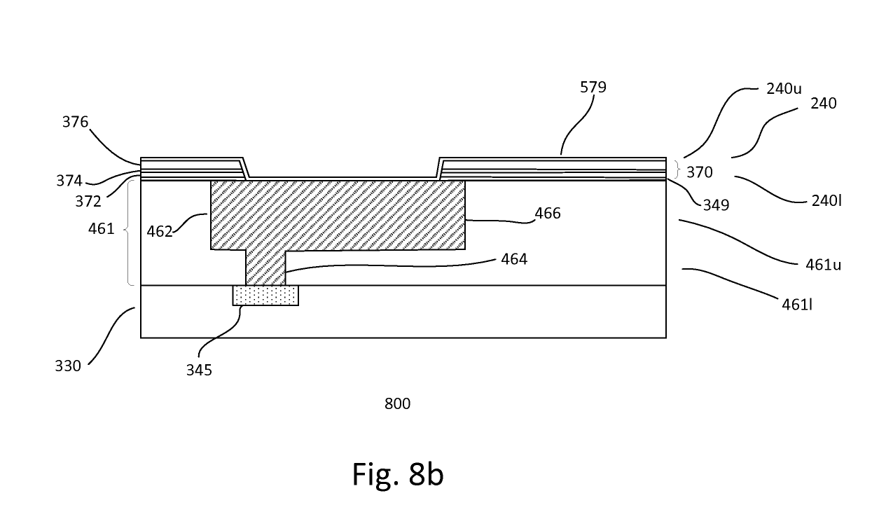

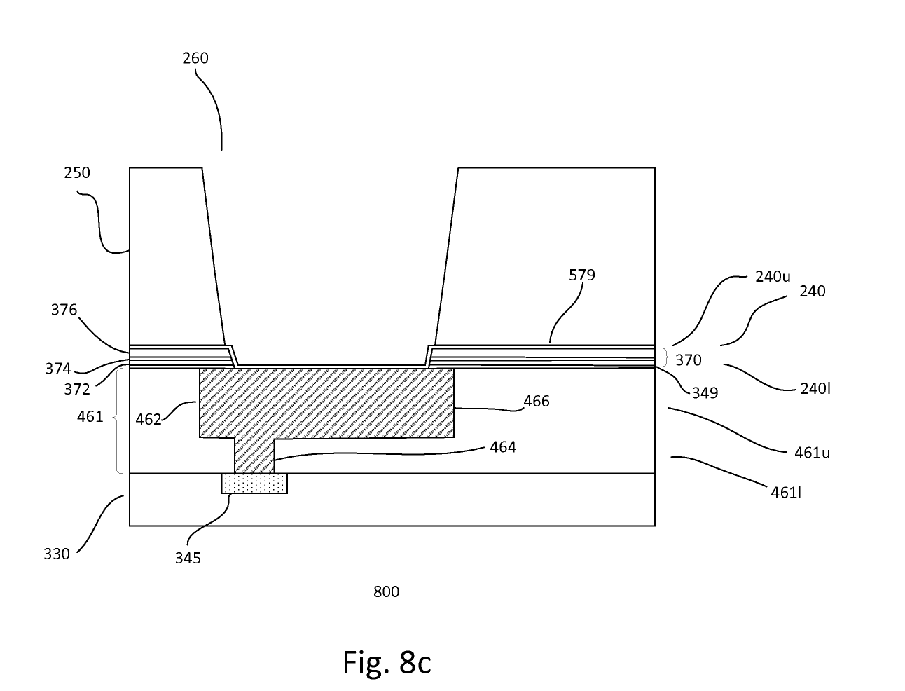

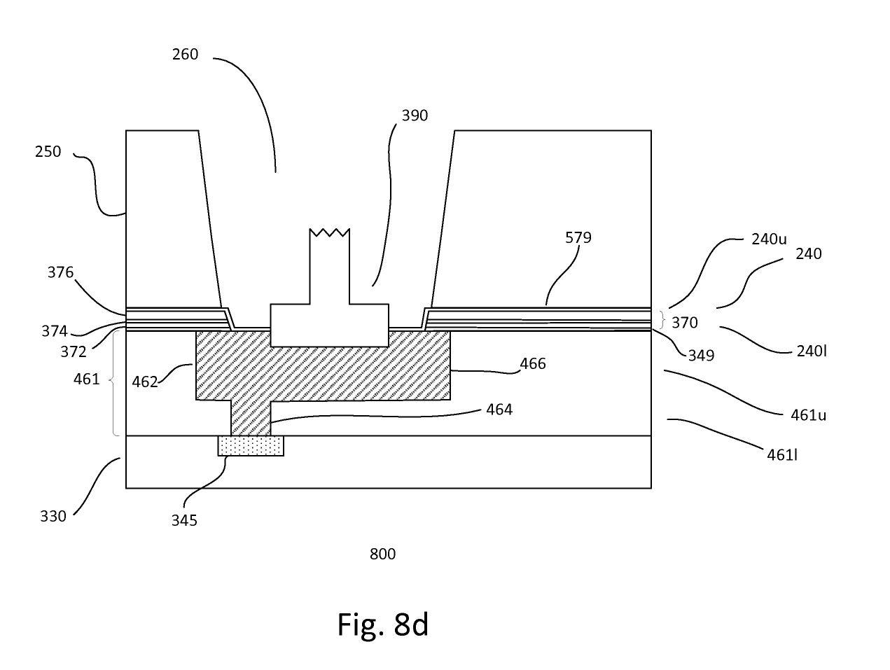

FIGS. 8a-8d show another embodiment of a process for forming a device 800. The process relates to forming pad interconnects in a device. Referring to FIG. 8a, a simplified portion of the device is shown. The device may be similar to that described in FIGS. 2, 3a-3b, 4a-4b, 5a-5b, 6a-6g and 7a-7f. Common elements may not be described or described in detail. The device, as shown, is in the stage of processing as described in FIG. 7b. For example, a lower pad level 240l of second pad level is disposed over a first or UTM pad level 461 with a UTM pad interconnect 462. The second pad level, for example, may be a thin pad level. The lower thin pad level includes a passivation layer 370 formed, for example, over a dielectric liner 349. The passivation layer, in one embodiment, is a primary passivation layer, as already described. Other types of passivation layers may also be useful. The lower thin pad level is patterned to form a via opening 778 which exposes the UTM interconnect.

In FIG. 8b, a protective layer 579 is formed on the substrate. The protective layer lines the surface of the primary passivation layer and UTM pad interconnect. In one embodiment, the protective layer is a dielectric layer. The protective layer, for example, is a thin protective layer having a thickness of about 7 nm. In one embodiment, the protective layer is a nitride layer. The nitride layer, for example, may be formed by CVD. Other types of thin protective layers or thicknesses may also be useful. The protective layer, for example, forms an upper thin dielectric level 240u of the second pad level.

Referring to FIG. 8c, a final passivation layer 250, is formed on the surface of the substrate. The final passivation layer covers the protective layer and fills the via opening. Forming the final passivation layer may be achieved by a single mask lithography process, such as a spin coating process. For example, the lithography process is self-planarizing. In one embodiment, the final passivation layer is a polyimide layer, such as a photosensitive polyimide layer. The passivation layer may be, for example, about 5 μm thick. Other thicknesses may also be useful. The passivation layer serves as the final passivation level.

A pad opening 260 is formed in the final passivation layer, exposing the protective layer lining the via opening and UTM pad interconnect. To form the pad opening, the final passivation layer may be exposed by an exposure source using a reticle with the desired pattern. After exposure, the polyimide layer is developed to create the opening, transferring the pattern of the reticle to the polyimide layer. In one embodiment, the pad opening is smaller than the underlying UTM pad interconnect. For example, the opening does not overlap the UTM pad dieletric layer.

In one embodiment, after forming the pad opening, the wafer is diced to separate the devices into individual chips. Referring to FIG. 8d, a wire bonding process bonds a wire bond 390 to the pad contact of the pad interconnect. The wire bond is, for example, a copper wire bond. Other types of wire bonds may also be useful.

As described, the device includes one pad interconnect. However, it is understood that a device may include numerous pad interconnects which are bonded with wire bonds. Furthermore, a thin protective layer is provided over the UTM pad contact. For example, a thin nitride layer is provided over the copper UTM pad contact. The thin protective layer reduces or prevents oxidation of the copper UTM pad contact. Furthermore, the bonding force easily splashes the thin protective layer to bond the wire bond to the underlying UTM pad contact. In addition, the use of a copper UTM pad contact facilitates copper wire bonding. For example, a copper UTM pad contact avoids the formation of intermetallic compounds by providing copper-to-copper bonding with the copper wire bond. The copper UTM pad contact may also serve as a stress buffer during wire bonding.

The present disclosure may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A method of forming a device comprising:
providing a substrate prepared with circuits component and a dielectric layer with interconnects;
forming a pad level over the dielectric layer, wherein forming the pad level comprises forming lower and upper pad levels, wherein
forming the lower pad level comprises
forming a primary passivation layer having at least a silicon oxide and silicon nitride layer, wherein the silicon nitride layer is the upper most layer of the primary passivation layer, and
patterning the primary passivation layer to form a pad via opening, the pad via opening exposing an interconnect in the dielectric layer below, and
forming the upper pad level comprises
forming a pad interconnect, the pad interconnect is disposed over the primary passivation layer around the via pad opening and contacts the exposed interconnect in the dielectric layer below;
forming a final passivation layer comprising polyimide on the substrate, wherein the final passivation layer contacts the primary passivation layer and pad interconnect;
forming a pad opening in the final passivation layer to expose the pad interconnect; and
receiving a wire bond at the pad interconnect.

2. The method of claim 1 wherein the pad interconnect is an aluminum interconnect.

3. The method of claim 1 wherein the wire bond is a copper or gold wire bond.

4. The method of claim 1 wherein the device is devoid of a secondary passivation layer between the pad interconnect and final passivation layer.

5. The method of claim 1 wherein the interconnect is a copper interconnect in communication with the pad interconnect.

6. A method of forming a device comprising:
providing a substrate prepared with circuits component and a dielectric layer with interconnects;
forming a pad level over the dielectric layer, wherein forming the pad level comprises forming lower and upper pad levels, wherein
forming the lower pad level comprises
forming a pad interconnect, the pad interconnect is disposed over the dielectric layer and contacts the interconnect in the dielectric layer below, and
forming the upper pad level comprises
forming a primary passivation layer having at least a silicon oxide and silicon nitride layer, wherein the silicon nitride layer is the upper most layer of the primary passivation layer,
patterning the primary passivation layer to form a pad via opening, the pad via opening exposing the pad interconnect in the lower pad level, and
forming a protective layer over the substrate, the protective layer covers the primary passivation layer and lines the pad via opening;
forming a final passivation layer comprising polyimide on the substrate, wherein the final passivation layer contacts the protective layer;
forming a pad opening in the final passivation layer to expose the pad via opening lined with the protective layer; and
receiving a wire bond at the pad interconnect, wherein the wire bond breaks through the protective layer.

7. The method of claim 6 wherein the protective layer comprises a thin conductive layer.

8. The method of claim 7 wherein the conductive layer is a thin aluminum layer.

9. The method of claim 8 wherein the aluminum layer thickness is about 0.7 μm.

10. The method of claim 9 wherein the protective layer comprises a thin dielectric layer.

11. The method of claim 10 wherein the dielectric layer is a thin nitride layer.

12. The method of claim 11 wherein the nitride layer thickness is about 7 nm.

13. The method of claim 9 wherein:
the wire bond comprises a first metallic material;
the pad interconnect comprises a second metallic material; and
the first and second metallic materials avoid the formation of intermetallic compound during wire bonding.

14. The method of claim 9 wherein:
the pad interconnect is an ultra-thick metal (UTM) pad interconnect; and
the pad opening is smaller than the UTM pad interconnect.

15. The method of claim 9 wherein:
the pad interconnect comprises a pad contact and a pad via contact; and
the interconnect is a copper interconnect in communication with the pad via contact.

16. The method of claim 9 wherein:
the upper pad level is a thin pad level; and
the lower pad level is an ultra-thick metal (UTM) pad level.

17. A semiconductor device comprising:
a substrate comprising circuit components and a dielectric layer with interconnects;
a pad level disposed over the dielectric layer, wherein the pad level comprises lower and upper pad levels, wherein
the lower pad level comprises
a pad interconnect, the pad interconnect is disposed over the dielectric layer and contacts the interconnect in the dielectric layer below, and
the upper pad level comprises
a primary passivation layer having at least a silicon oxide and silicon nitride layer, wherein the silicon nitride layer is the upper most layer of the primary passivation layer,
a pad via opening disposed in the primary passivation layer and above the pad interconnect, and
a protective layer disposed in the pad via opening, wherein the protective layer lines the pad interconnect;
a final passivation layer comprising polyimide disposed on the substrate, wherein the final passivation layer contacts the protective layer;
a pad opening disposed in the final passivation layer; and
a wire bond attached to the pad interconnect through the protective layer.

18. The device of claim 17 wherein the protective layer is a thin conductive layer.

19. The device of claim 17 wherein the protective layer is a thin dielectric layer.

20. The device of claim 17 wherein the wire bond and the pad interconnect comprises a same metallic material.
